(19) United States
(12) Patent Application Publication
(10) Pub. No.: US 2022/0146563 A1
(43) Pub. Date: May 12, 2022

(54) OVERHEAD ELECTRICAL CABLE INTERROGATION SYSTEMS AND METHODS

(71) Applicant: CTC Global Corporation, Irvine, CA (US)

(72) Inventors: Xiaoyuan Dong, Johns Creek, GA (US); William Webb, Laguna Niguel, CA (US)

(21) Appl. No.: 17/436,644

(22) PCT Filed: Mar. 6, 2020
(86) PCT No.: PCT/US2020/021535

§ 371 Date: Sep. 6, 2021

Related U.S. Application Data
(60) Provisional application No. 62/814,372, filed on Mar. 6, 2019.

(51) Int. Cl. G01R 31/08; H01B 9/00; G02B 6/02

(52) U.S. Cl. CPC G01R 31/085; G02B 6/02395; H01B 9/008; H01B 9/005

(57) ABSTRACT

Systems and methods for the interrogation of an overhead electrical cable using a coherent light source, such as a laser. The systems and methods may include the isolation of one or more optical fibers that are embedded in or attached to a strength member of the electrical cable, and the connection of an interrogation device such as an OTDR device to the optical fibers for the purpose of interrogating the overhead electrical cable to determine a state of the cable, such as temperature or mechanical strain.

### CROSS-REFERENCE TO RELATED APPLICATIONS

This application claims the priority benefit of U.S. Provisional Application Ser. No. 62/814,372 filed Mar. 6, 2019, which is incorporated herein by reference in its entirety.

### FIELD

This disclosure relates to the field of overhead electrical cables that include a strength member supporting an outer conductive layer, and particularly to methods and systems for interrogating electrical conductor cables to ascertain if the cable, particularly the strength member, has been damaged.

### BACKGROUND

Overhead electrical cables typically include a plurality of conductive stands that are wrapped around and supported by a strength member. Traditionally, the strength member was fabricated from a plurality of steel strands, a configuration referred to as aluminum conductor steel reinforced (ACSR). Because fiber-reinforced composite strength members offer many advantages over other strength member materials such as steel, overhead electrical cables including composite strength members are being implemented in many new electrical transmission line projects. Such overhead electrical cables are also being used to re-conductor existing transmission lines, e.g., to replace ACSR conductor cables on existing infrastructure (e.g., existing support towers).

While the steel strength members in an ACSR configuration can be sharply bent and can deform plastically without exhibiting substantial strength degradation, many fiber-reinforced composite materials do not deform plastically, and simply store kinetic energy when they are bent. This stored kinetic energy advantageously allows a flexible fiber-reinforced composite to return to its original shape as the bending load is released. When the bending load is excessive, however, even a flexible fiber-reinforced composite material may be damaged in either a compressive or tensile failure mode. Should some initial damage occur, this damage may propagate over time causing further degradation or complete failure of the strength member.

The utility industry has also recently expressed a desire for products and methods to diagnose transmission line health, to optimize operation of the transmission lines, to reduce maintenance costs and to reduce the likelihood of catastrophic failures of the power transmission grid. However, power transmission lines include geographically diverse and remotely located pieces of infrastructure, in addition to being many kilometers in length. It is extremely difficult to monitor the entire transmission line, to identify problems in the transmission line with a high degree of accuracy with respect to the nature and the location of the problem, and to transmit data relevant to the problem to a central location, e.g., for analysis.

There is also a desire to utilize transmission grids to their maximum potential and operate the transmission line segments closer to the edge of reliability. However, operating under such conditions creates a higher likelihood of a failure event in the transmission grid, e.g., the failure of an overhead electrical cable in the transmission grid.

### SUMMARY

It would be desirable to have the ability to interrogate a fiber-reinforced composite strength member to identify the presence of defects or flaws in the strength member and to measure elongation. It would be particularly desirable to identify such defects or flaws early in the product cycle of manufacture, installation and use of the composite strength member in an overhead electrical cable.

One problem that has been identified with respect to the interrogation of overhead electrical cables using sensing optical fibers is that it is extremely difficult to selectively access the sensing fibers from within the composite matrix and make a reliable connection between the sensing optical fibers and the OTDR device. That is, the sensing optical fibers have a relatively small diameter, and are difficult to locate and connect to when they are disposed within the same matrix as the structural fibers. This problem is particularly difficult in the context of overhead electrical cable installations because the connections must be made in the field by technicians, often under difficult environmental conditions.

Accordingly, the products, methods and systems disclosed herein may enable interrogation of fiber-reinforced composite strength members to detect flaws in the composite strength member: (i) after manufacture and before installation (e.g., a manufacturing flaw); (ii) after stranding with an electrically conductive layer to form an electrical conductor and before installation (e.g., to detect a flaw introduced during stranding); and/or after installation of the overhead electrical cable but before energizing the electrical conductor (e.g., a flaw due to a failure to follow installation protocols). By determining if flaws are present in the composite strength member and/or the conductive layer at one or more of these points in the product manufacture and installation cycle, not only can time and costs be saved due to early detection, but remedial steps may be taken to correct the manufacturing or installation mistakes that caused the flaws.

It may also be advantageous to ascertain a condition of the composite strength member such as the temperature, the strain conditions of the strength member, or the elongation (e.g., the change in length) of the strength member, and hence of the overhead electrical cable, immediately after energizing the installed overhead electrical cable in a power transmission line. Accordingly, the products, methods and systems disclosed herein may also enable the interrogation of the overhead electrical cable to ascertain one or more conditions of the overhead electrical cable immediately after energizing the overhead electrical cable. For example, the installation of the overhead electrical cable may result in surface defects on the electrically conductive layer that give rise to “hot spots” where the resistivity of the conductive layer is unacceptably high.

In another aspect, conditions of the overhead electrical cable may be monitored after installation and during use of the overhead electrical cable in normal power transmission operations, e.g., in a power transmission grid. Monitoring the conditions of the overhead electrical cable is highly desirable, particularly due to weather events (e.g., wind, ice loading) or inadvertent incidents (e.g., conductor over-loading, damage to conductive layer etc.). For example, the operating temperature of the overhead electrical cable may be measured on a continuous or a periodic basis. In another aspect, the tensile strain in the overhead electrical cable (i.e., the tensile strain in the strength member) may be measured continuously or periodically. In yet another aspect, the length of the overhead electrical cable (i.e., the length of the strength member) may be measured continuously or periodically. Such measurements may be used to determine different states of the overhead electrical cable, such as the real-time sag of the overhead electrical cable at any given span in the transmission line for greater system safety and reliability.

In one characterization, the products, systems and methods incorporate the use of distributed fiber optic sensors. The distributed fiber optic sensors may include a sensing optical fiber that is disposed along a length of the composite strength member and may be disposed within the strength member, e.g., within a binding matrix of the strength member. Through the use of a distributed fiber optic sensor, certain conditions of the overhead electrical cable (e.g., temperature or strain) may be determined at substantially any point along the length of the overhead electrical cable with a high degree of accuracy, both with respect to the quantitative measurement of the condition and the location of that condition. In this manner, for example, “hot-spots” along the length of the overhead electrical cable may be identified, which may indicate a point of greater electrical resistance due to a flaw in the conductive layer or the core.

Further, through the use of distributed optical fiber sensors, the tensile strain in the strength member may be determined at different locations along its length, such as to identify the location of abrupt changes in tensile strain. Such abrupt changes may indicate a problem with the overhead electrical cable, such as a flaw in the composite strength member due to natural or human-based events. By early and accurate detection of such flaws, corrective action may be taken before the flaws lead to a serious failure of the transmission line.

It may be desirable to operatively couple the sensing and monitoring devices with communication modules that are configured to transmit the data to a location where the data can be monitored, recorded and/or analyzed, and leveraged. Based on the analysis, the power transmission grid may be operated, e.g., to increase or decrease the power that is sent through the overhead electrical cable. Further, location information for various conditions (e.g., hot-spots) may be utilized to effectively and efficiently deploy maintenance teams to that location to further inspect and correct the issue, if necessary.

In one embodiment, a system for detecting a tensile strain condition of an overhead electrical cable is disclosed. The system includes at least a first overhead electrical cable that forms a segment of a power transmission line, the overhead electrical cable comprising a fiber-reinforced composite strength member, the strength member comprising a binding matrix and structural fibers disposed within the binding matrix, and an electrically conductive layer wrapped around and supported by the fiber-reinforced strength member. The system also includes a sensor component that is integrated with the overhead electrical cable and is configured to measure, e.g., the tensile strain of the overhead electrical cable, the sensor component comprising at least a first sensing optical fiber that is integrally formed within the binding matrix of the strength member and is disposed along a length of a neutral axis of the strength member. The first sensing optical fiber is configured for distributed sensing of, e.g., tensile strain along the length of the overhead electrical cable. The system also includes at least a first laser source that is configured to transmit a coherent light pulse down the length of the first sensing optical fiber, and at least a first signal detector that is configured to detect at least a first backscattered light component that is backscattered by the first sensing optical fiber to the detector and provide data relating to at least the tensile strain in the overhead electrical cable.

In one characterization, the sensor component comprises at least a second sensing optical fiber, the second sensing optical fiber being offset from the neutral axis along the length of the strength member, wherein the second sensing optical fiber is configured for distributed sensing of temperature along the length of the overhead electrical cable. In another characterization, the first sensing optical fiber is substantially linearly disposed along the length of the neutral axis. In another characterization, the first sensing optical fiber is a single mode optical fiber. In another characterization, the first sensing optical fiber is a silica-based optical fiber. In another characterization, the second sensing optical fiber is a multi-mode optical fiber. In another characterization, the second sensing optical fiber is offset from the neutral axis by a distance equal to at least about 20% of the diameter of the strength member. In another characterization, the second sensing optical fiber is integrally formed within the binding matrix of the strength member. In another characterization, the second sensing optical fiber is disposed between the binding matrix of the strength member and a material layer surrounding the binding matrix. In another characterization, the structural fibers comprise carbon fibers. In another characterization, the structural fibers comprise glass fibers. In another characterization, the structural fibers comprise at least fibers of a first type and fibers of a second type that is different than the first type. In another characterization, the structural fibers comprise substantially continuous structural fiber tows. In another characterization, the overhead electrical cable has a length of at least about 1000 meters. In another characterization, the strength member has a substantially circular cross-section. In another characterization, the strength member has a tensile strength of at least about 1400 MPa. In another characterization, the first signal detector is configured to detect at least a Brillouin backscattered light component that is backscattered by the first sensing optical fiber. In another characterization, the first signal detector is configured to detect at least a Raman backscattered light component that is backscattered by the second sensing optical fiber. In another characterization, the first signal detector is configured to detect at least the length of the overhead electrical cable. In another characterization, the strength member comprises a single unitary fiber-reinforced composite member. In another characterization, the first signal detector is configured to detect Rayleigh backscattered light by optical time domain reflectometry.

In another embodiment, an intelligent power transmission system is disclosed. The system includes at least a first overhead electrical cable that is strung under tension between a first dead-end tower and a second dead-end tower and is supported by a plurality of suspension towers between the first and second dead-end towers to form a segment of a power transmission line. The first overhead electrical cable includes a strength member and an electrically conductive layer disposed around and supported by the strength member. At least a first sensing optical fiber is disposed within the first overhead electrical cable, wherein the first sensing optical fiber is configured for distributed sensing of at least one of composite damage, tensile strain and temperature along the length of the first overhead electrical cable. The system also includes at least a first pump laser source that is operatively supported by the first dead-end tower and that is configured to direct a coherent light signal pulse into a first end of at least the first sensing optical fiber, a signal detector that is operatively supported on the first dead-end tower and that is configured to detect at least one of a Brillouin backscattered light component and a Raman backscattered light component of the coherent light signal pulse that is backscattered to the signal detector by the first sensing optical fiber, and a transmission unit operatively supported by the first dead-end tower that is configured to transmit data pertaining to the backscattered light component to a monitoring facility that is remote from the first dead-end tower.

In one characterization, the system includes a second overhead electrical cable that is strung under tension between the first dead-end tower and the second dead-end tower and is supported by the plurality of suspension towers, the second overhead electrical cable comprising a strength member, an electrically conductive layer disposed around and supported by the strength member, and at least a first sensing optical fiber that is disposed within the second overhead electrical cable, wherein the first sensing optical fiber is configured for distributed sensing of at least one of tensile strain and temperature along the length of the second overhead electrical cable. The first pump laser source is configured to direct a coherent light signal pulse into a first end of the first sensing optical fiber and into a first end of the second sensing optical fiber.

In another characterization, a dead-end fitting attaches the overhead electrical cable to the dead-end tower and wherein the first laser source is operatively integrated with the dead-end fitting. In another characterization, at least a second laser source is configured to direct a counter-propagating probe light signal pulse through at least the first sensing optical fiber. In another characterization, the distance between the first and second dead-end towers is at least about 1500 meters. In another characterization, the distance between the first and second dead-end towers is not greater than about 6000 meters.

In another embodiment, an overhead electrical cable that is configured for use in a transmission line segment is disclosed. The fiber-reinforced composite strength member comprises a resin matrix and structural fibers disposed within the resin matrix, an electrically conductive layer wrapped around and supported by the strength member, and at least a first sensing optical fiber that is integrally formed within the resin matrix of the strength member and is disposed along a length of a neutral axis of the strength member, wherein the first sensing optical fiber is configured for distributed sensing of tensile strain along the length of the overhead electrical cable.

In one characterization, the cable includes at least a second sensing optical fiber, the second sensing optical fiber being offset from the neutral axis along the length of the strength member, wherein the second sensing optical fiber is configured for distributed sensing of temperature along the length of the overhead electrical cable. In another characterization, the first sensing optical fiber is substantially linearly disposed along the length of the neutral axis. In another characterization, the first sensing optical fiber is a single mode optical fiber. In another characterization, the first sensing optical fiber is a silica-based optical fiber. In another characterization, the second sensing optical fiber is a multi-mode optical fiber. In another characterization, the second sensing optical fiber is offset from the neutral axis by a distance equal to at least about 20% of the diameter of the strength member. In another characterization, the second sensing optical fiber is integrally formed within the resin matrix of the strength member. In another characterization, the second sensing optical fiber is disposed between the resin matrix of the strength member and a material layer surrounding the resin matrix. In another characterization, the structural fibers comprise carbon fibers. In another characterization, the structural fibers comprise glass fibers. In another characterization, the structural fibers comprise substantially continuous structural fiber tows. In another characterization, the overhead electrical cable has a length of at least about 1000 meters. In another characterization, the fiber-reinforced composite member has a tensile strength of at least about 1400 MPa.

### DESCRIPTION OF THE DRAWINGS

FIG. 1 illustrates a perspective view of an overhead electrical cable.

FIGS. 2A-2F illustrate cross-sectional views of fiber-reinforced composite members.

FIGS. 3A-3B illustrate a perspective cross-sectional view of fiber-reinforced composite members having sensing optical fibers disposed along a length thereof.

FIG. 4 illustrates a perspective cross-sectional view of an electrical conductor including a fiber-reinforced composite strength member having two sensing optical fibers disposed along a length thereof.

FIG. 5 illustrates a perspective view of an overhead transmission line.

FIG. 6 illustrates the components of a backscattered light signal that may be analyzed using a distribution sensor system.

FIG. 7 schematically illustrates a connection system for coupling optical fibers from a composite strength member to an interrogation device.

FIG. 8 schematically illustrates an arrangement for protecting optical fibers and for facilitating the coupling of the optical fibers to an interrogation device.

FIG. 9 schematically illustrates the attachment of optical fiber(s) to a fiber alignment apparatus.

FIG. 10 schematically illustrates a method and apparatus for the chemical removal of a binding matrix to expose optical fibers.

FIG. 11 schematically illustrates a method and apparatus for the thermal removal of a binding matrix to expose optical fibers.

### DESCRIPTION

Broadly stated, disclosed herein are products, methods and systems that enable the continuous and/or periodic interrogation of the fiber-reinforced composite strength member in an overhead electrical cable to ascertain one or more conditions (e.g., mechanical or thermal conditions) of the fiber-reinforced composite strength member. The determined conditions may be used alone or in combination (e.g., via an algorithm) to make refined determinations about the state of the fiber-reinforced composite member and/or the environment surrounding the fiber-reinforced composite member of one or more locations along its length. The products, methods and systems have particular usefulness for the interrogation and monitoring of overhead electrical cables comprising the composite strength member that form transmission and distribution lines used in a power transmission grid for the transmission of electricity, particularly over long distances.

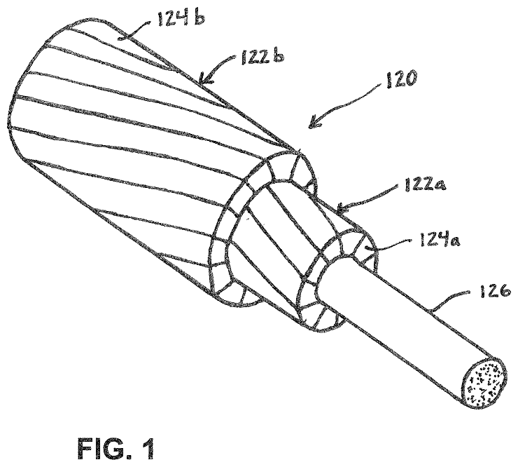

One example of such an overhead electrical cable is schematically illustrated in FIG. 1. The overhead electrical cable 120 includes a first conductive layer 122a comprising a plurality of conductive strands 124a that are helically wrapped around a composite strength member 126. The conductive strands 124a may be fabricated from conductive metals such as copper or aluminum, and typically are fabricated from aluminum, e.g., hardened aluminum, annealed aluminum, and/or aluminum alloys. As illustrated in FIG. 1, the conductive strands 124a have a substantially trapezoidal cross-section, although other configurations may be employed, such as circular cross-sections. The use of polygonal cross-sections such as the trapezoidal cross-section advantageously increases the cross-sectional area of conductive metal for the same effective cable diameter, e.g., as compared to strands having a circular cross-section. As illustrated in FIG. 1, the overhead electrical cable 120 also includes a second conductive layer 122b comprising a plurality of conductive strands 124b that are helically wound around the first conductive layer 122a. It will be appreciated that such overhead electrical cables may include a single conductive layer, or more than two conductive layers, depending upon the desired use of the overhead electrical cable.

As noted, the conductive layers 124a/124b fabricated from, e.g., aluminum, do not have sufficient mechanical properties (e.g., sufficient tensile strength) to be self-supporting when strung between support towers to form an overhead conductor line. Therefore, the overhead electrical cable 120 includes the strength member 126 to support the conductive layers 124a/124b when the overhead electrical cable 120 is strung between the support towers under high mechanical tension. Traditional strength members were fabricated from steel, specifically a plurality of steel elements (e.g., rods) wrapped together to form the strength member. Recently, steel strength members have been replaced by a strength member fabricated from composite materials, for example fiber-reinforced composites, which offer many significant benefits. Such composite strength members may consist of a single-element (e.g., single rod) as is illustrated in FIG. 1. An example of such a configuration is illustrated in U.S. Pat. No. 7,368,162 by Hiel et al., which is incorporated herein by reference in its entirety. Alternatively, the composite strength member may be comprised of a plurality of individual composite elements (e.g., individual rods) that are operatively combined (e.g., helically twisted together) to form the strength member. Examples of such multiple-element composite strength members include, but are not limited to: the multi-element aluminum matrix composite strength member illustrated in U.S. Pat. No. 6,245,425 by McCullough et al.; the multi-element carbon fiber strength member illustrated in U.S. Pat. No. 6,015,953 by Tosaka et al.; and the multi-element strength member illustrated in U.S. Pat. No. 9,685,257 by Daniel et al. Each of these U.S. patents is incorporated herein by reference in its entirety.

Broadly characterized, a fiber-reinforced composite strength member may include a binding matrix and a plurality of structural fibers that are operatively disposed (e.g., embedded) within the binding matrix, i.e., where the matrix binds the structural fibers together to form the composite member.

The binding matrix in which the structural fibers are embedded may include any type of inorganic or organic material that may operatively embed and bind the structural fibers into a fiber-reinforced composite strength member. Thus, the binding matrix may predominately include, for example, an inorganic material such as a ceramic or a metal. In another characterization, the binding matrix may predominately include an organic material, such as a polymer, e.g., a synthetic polymer.

For example, the binding matrix may include a thermoplastic polymer, including semi-crystalline thermoplastics. Specific examples of useful thermoplastics include, but are not limited to, polyether ether ketone (PEEK), polypropylene (PP), polypropylene sulfide (PPS), polyetherimide (PEI), liquid crystal polymer (LCP), polyoxymethylene (POM, or acetal), polyamide (PA, or nylon), polyethylene (PE), fluoropolymers and thermoplastic polyesters. Other examples of polymeric materials useful for a binding matrix may include addition cured phenolic resins (e.g., bismaleimides), polyetheramides, various anhydrides, or imides.

In one characterization, the binding matrix includes a thermoset polymer such as an epoxy resin (e.g., epoxies). Examples of useful epoxy resins include, but are not limited to, benzoxazine, thermosetting polyimides (PI), polyether amide resin (PEAR), phenolic resins, epoxy-based vinyl ester resins, polycyanate resins and cyanate ester resins. In one exemplary embodiment, a vinyl ester resin is used in the binding matrix. Another embodiment includes the use of an epoxy resin that is a reaction product of epichlorohydrin and bisphenol A. Yet another embodiment includes the use of a bisphenol A diglycidyl ether (DGEBA).

Curing agents (e.g., hardeners) for the epoxy resins may be selected according to the desired properties of the fiber-reinforced composite strength member and the processing method. For example, curing agents may be selected from aliphatic polyamines, polyamides and modified versions of these compounds.

The epoxy resin may also be selected to provide resistance to a broad spectrum of aggressive chemicals, and may be selected to have stable dielectric and insulating properties. It may be advantageous that the resin meets ASTME595 out-gassing standards and UL94 flammability standards, and is capable of operating at least intermittently at temperatures ranging between about 100° C. and 200° C. without substantial degradation (e.g., thermal or mechanical degradation) of the fiber-reinforced composite strength member.

The epoxy resin may also include components to assist in fabrication and/or to improve the properties of the binding matrix. For example, a thermoset epoxy resin system for achieving the desired properties of the fiber-reinforced composite strength member, as well as ease of fabrication, may incorporate a catalyst. The catalyst (e.g., an “accelerator”) may be selected to facilitate curing of the epoxy resin components in a short time and/or with reduced side reactions that may cause cracking of the cured resin matrix. It may also be desirable for the catalyst to be relatively inactive at low temperatures for increased resin life (e.g., “pot life”), and very active at higher temperatures for increased manufacturing speed during fabrication of the composite strength member. The epoxy resins may also be further modified with additional processing aids (e.g., mold release agents) as well as performance-enhancing fillers, e.g., for toughening or stiffening the matrix, e.g., with elastomers, thermoplastics and the like.

The fiber-reinforced composite strength members also include a plurality of structural fibers operatively disposed in (e.g., dispersed throughout) the binding matrix. The structural fibers may include substantially continuous fibers (e.g., fiber tows) and/or may include discontinuous fibers (e.g., fiber whiskers). The structural fibers may be aligned within the binding matrix (e.g., an isotropic composite) or may be randomly disposed within the binding matrix (e.g., an anisotropic composite). In one characterization, the structural fibers include continuous fibers, such as in the form of one or more elongate fiber tows disposed throughout the binding matrix. A fiber tow is an untwisted bundle of substantially continuous individual filaments, often comprising several thousand individual fibers in a single fiber tow.

Structural fibers used in the fiber-reinforced composite strength members may be selected from synthetic fibers or natural fibers. In another characterization, the structural fibers may be selected from organic fibers or inorganic fibers. For example, the structural fibers may include carbon fibers (e.g., graphite fibers or carbon nanofibers), aramid fibers such as KEVLAR™, glass fibers (including basalt fibers), ceramic fibers, boron fibers, liquid crystal fibers, high performance polyethylene fibers (e.g., SPECTRA fibers), steel fibers (e.g., steel hardwire filaments), including high carbon steel fibers, or fibers based on carbon nanotubes. The fibers may optionally be coated to enhance processing and/or mechanical properties, such as by using adhesive enhancing coatings.

In one characterization, the structural fibers include carbon fibers such as those selected from high strength (HS) carbon fibers, intermediate modulus (IM) carbon fibers, high modulus (HM) carbon fibers and ultra-high modulus (UHM) carbon fibers. The carbon fibers may be fabricated from precursors such as rayon, polyacrylonitrile (PAN) or petroleum pitch. Non-limiting examples of useful carbon fibers include those from the ZOLTEK PANEX™, ZOLTEK PYRON™, HEXCEL™, TORAY™, GRAFIL, or THORNEL™ families of carbon fiber products. Other examples of carbon fibers may include TORAY M46J, TORAY T700 SC-24K, TORAY T700SC-12K, GRAFIL TRH50-18M, TORAY T800H-12K, TORAY T1000G, PyroFil TR-50S or rayon byproducts, among others. One skilled in the art will recognize the numerous carbon fiber types that may be used in the fiber-reinforced composite strength members.

Different types of glass fibers may also be useful in the fiber-reinforced composite strength members, either alone or in combination with other fiber types such as carbon. For instance, A-Glass, B-Glass, C-Glass, D-Glass, E-Glass, H-Glass, S-Glass, AR-Glass, R-Glass, or basalt (e.g., volcanic glass) fibers may be used in the composite strength members. Fiberglass and paraglass may also be used. For example, S-2 Glass 758-AB-225, S-2 Glass 758-AB-675; E-Glass 366-AC-250; E-Glass 366-AB-450, E-Glass 366-AB-675, and basalt containing E-Glass may all be useful for the structural fibers. In one example, a boron-free glass such as E-Glass is used as a glass fiber.

Ceramic fibers may also be useful as structural fibers in the composite strength members. Such ceramic fibers may include, for example, carbide fibers such as silicon carbide fibers (SiC), nitride fibers such as silicon nitride fibers (Si₃N₄), metal oxide fibers such as zirconia-based fibers (ZrO₂), alumina fibers (Al₂O₃), aluminosilicate fibers and aluminoborosilicate fibers. Examples of reinforcing ceramic fibers are those available from the 3M Company (St. Paul, Minn., USA) under the brand name NEXTEL, such as NEXTEL continuous filament ceramic oxide fibers 312, 440, 550, 610 and 720. Although described herein as ceramic fibers, it will be appreciated that such fibers may include both crystalline and glassy (e.g., amorphous) material phases.

In one characterization, the composite strength member may include at least two fiber types, i.e., fibers of at least two different material compositions and/or different fiber types. The two or more fiber types may be intermixed or may be disposed in discrete sections of a fiber-reinforced composite strength member, e.g., in concentric sections. The two fiber types may be within one fiber material class. For instance, the composite strength member may include both E-Glass and S-Glass fibers, which are two different fiber types within the glass fiber class. In another example, the fiber-reinforced composite strength member may include two different fiber types within the carbon fiber class, e.g., an HS carbon fiber and an HM carbon fiber. Combinations of different fibers may be used, for example, to combine a more inexpensive fiber type with a more expensive fiber type to achieve the desired results at a reduced cost.

As is noted above, the structural fibers may also include discontinuous fibers (e.g., whiskers), alone or in combination with continuous fibers. The discontinuous fibers may optionally be aligned within the binding matrix to form an isotropic fiber-reinforced composite member, or may be randomly oriented within the binding matrix.

In one particular embodiment, the fiber-reinforced composite strength member includes structural fibers that extend substantially continuously through the length of the strength member. For example, the fiber-reinforced composite strength members may include one or more elongate structural fiber tows dispersed within a resin matrix. A fiber tow is a bundle (e.g., untwisted) of continuous fibers (filaments), where the number of individual fibers in the tow is expressed as its yield (yards per pound), or as its K number. For example, a 12K fiber tow includes about 12,000 individual fibers. By way of example, fiber-reinforced composite strength members may be fabricated by selecting carbon fiber tows in the range of about 4K to about 60K, or greater. Glass fiber tows may typically be selected in the range of about 100 yield to about 1600 yield, e.g., from about 5000 tex to about 250 tex (g/km).

Typically, the diameter of individual structural fibers in the fiber tows may be selected to be at least about 8 μm and not greater than about 25 μm for glass fibers, such as glass fibers having a diameter of at least about 8 μm and not greater than about 18 μm. Carbon fibers may be selected having a diameter of at least about 4 μm and not greater than about 10 μm, such as carbon fibers having a diameter of at least about 5 μm and not greater than about 8 μm. Ceramic fibers may have a diameter of at least about 7 μm and not greater than about 13 μm, for example. For other classes of structural fibers, a suitable size range may be determined in accordance with the desired physical properties of the composite strength member, or based on the desired wet-out characteristics, or other manufacturing considerations. For example, structural fibers that are not greater than about 5 μm in diameter may pose certain health risks to those that handle the fibers. Structural fibers exceeding about 25 μm in diameter typically don't have the desired tensile properties and/or processability.

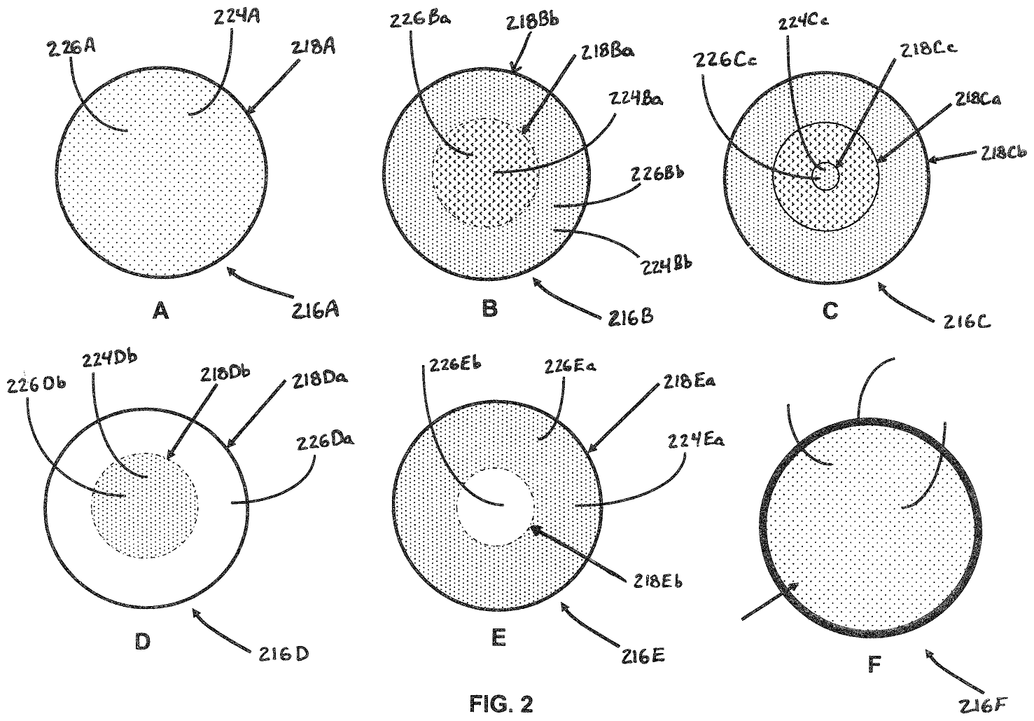

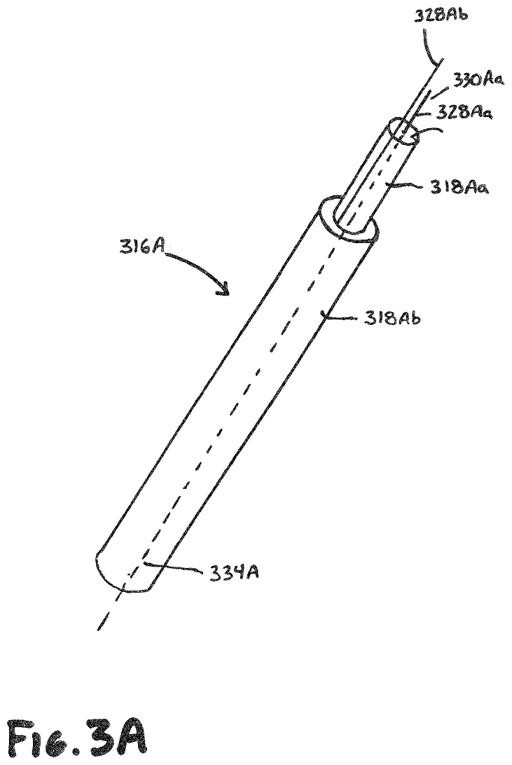

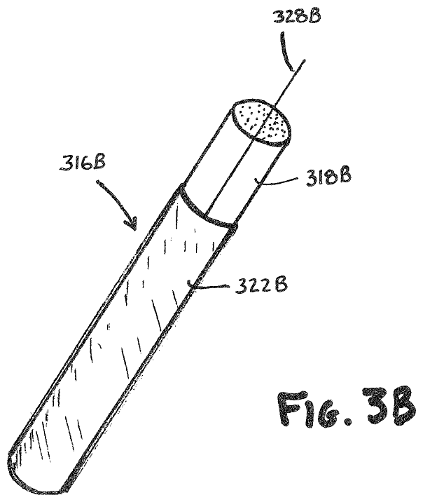

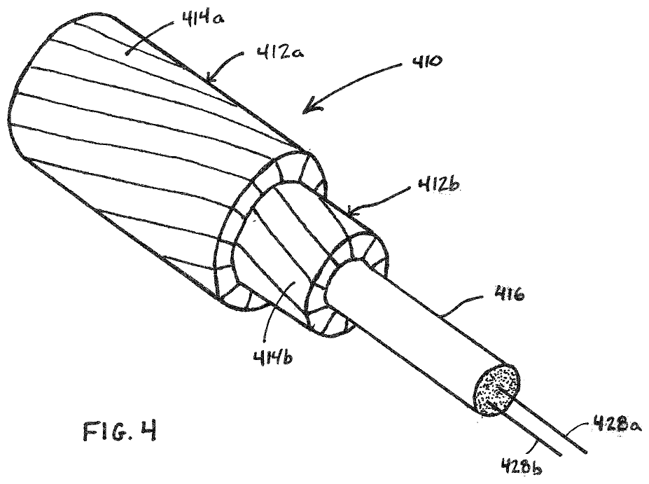

The fiber-reinforced composite strength members may have different cross-sectional shapes, such as polygonal cross-sectional shapes, oval cross-sectional shapes and virtually any other cross-sectional shape, including symmetrical and non-symmetrical shapes. Further, the placement of structural fibers within the binding matrix may include various cross-sectional configurations of layers or sections. By way of example, FIGS. 2A-2F illustrate several different cross-sectional configurations of fiber-reinforced composite strength members having a circular cross-sectional shape, e.g., taken perpendicular to the longitudinal axis of the composite strength members.

FIG. 2A illustrates a fiber-reinforced composite strength member 216A that includes a composite section 218A comprising a substantially uniform distribution of structural fibers 224A that are uniformly dispersed within a binding matrix 226A. The structural fibers 224A dispersed throughout the composite section 218A may be of a single fiber type (e.g., carbon, glass or ceramic) or may be a mixture of two or more fiber types (e.g., carbon and glass, carbon and ceramic, glass and ceramic, etc.).

The fiber-reinforced composite strength members may also include two or more distinct sections. FIG. 2B illustrates a fiber-reinforced composite strength member 216B that includes two distinct fiber-reinforced composite sections, where a first fiber-reinforced composite section 218Bb surrounds a second fiber-reinforced composite section 218Ba. The second composite section 218Ba may include first structural fibers 224Ba dispersed in a first binding matrix 226Ba, and the second fiber-reinforced composite section 218Ba may include second structural fibers 224Ba dispersed in a second binding matrix 226Ba. In this example, the first structural fibers 224Ba may be the same as, or may be different than, the second structural fibers 224Bb. For example, the second structural fibers 224Bb may be low modulus fibers that have a relatively low elastic modulus and/or are electrically insulative, such as glass fibers, and the first structural fibers 224Ba may be structural fibers having a higher elastic modulus and/or tensile strength than the first structural fibers 224Ba, such as carbon fibers. Further, the first binding matrix 226Ba may be the same as or different than the second binding matrix 226Bb. In one embodiment, the first binding matrix 226Ba and second binding matrix 226Bb include the same material (e.g., same epoxy resin), while the first structural fibers 224Ba are different than the second structural fibers 224Bb, e.g., the first and second structural fibers have at least one material property that is different. The different material property may be any material property, for example modulus of elasticity, electrical conductivity, tensile strength, elongation and/or coefficient of thermal expansion. As a result, the first and second composite sections 218Ba and 218Bb may have one or more different material properties, such as a different modulus of elasticity, electrical conductivity, tensile strength, elongation and/or coefficient of thermal expansion. In one characterization, the second composite section 218Bb has a higher modulus of elasticity and a lower electrical conductivity than the second composite section 218Bb. In another characterization, the first composite section 218Ba has a higher tensile strength than the first composite section 218Bb. The fiber-to-matrix ratio in the first fiber-reinforced composite section 218Ba may also be different than the fiber-to-matrix ratio in the second fiber-reinforced composite section 218Bb. The fiber-to-resin ratios may be varied irrespective of whether or not the structural fibers and the binding matrix materials of the sections are the same or are different.

In the embodiment illustrated in FIG. 2C, the fiber-reinforced composite strength member 216C includes a first fiber-reinforced section 218Ca that is surrounded by a second fiber-reinforced composite section 218Cb. The strength member 216C also includes a third fiber-reinforced composite section 218Cc that is surrounded by the first section 218Ca. As illustrated in FIG. 2C, the third section 218Cc includes third structural fibers 224Cc dispersed in a third binding matrix 226Cc. The third structural fibers 224Cc may be the same or different than the structural fibers of the first and/or second fiber-reinforced sections, and the third binding matrix 226Cc may be the same or different than the binding matrix of the first and/or second fiber-reinforced composite sections.

FIG. 2D illustrates another embodiment of a composite strength member 216D that includes a first material section 218Da surrounding a second material section 218Db. In this embodiment, the first material section 218Da includes a first material 226Da (e.g., a polymer) that is substantially devoid of structural fibers. Stated another way, the first section 218Da consists essentially of the “matrix” 226Da, e.g., of the matrix material. The first material section 218Da surrounds a fiber-reinforced second section 218Db that includes structural fibers 224Db dispersed in a second binding matrix 226Db. The first matrix 226Da may be the same or different than the second binding matrix 226Db. In one characterization, the structural fibers 224Db of the fiber-reinforced second section 218Db include carbon fibers, and the first material section 218Da insulates (e.g., electrically insulates) the carbon fibers. Further, the first material section 218Da which is substantially devoid of structural fibers may have a lower modulus of elasticity than the fiber-reinforced second section 218Db to provide a degree of flexibility to the composite strength member 216D.

In the embodiment illustrated in FIG. 2E, the composite strength member 216E includes a fiber-reinforced first material section 218Ea substantially surrounding a second section 218Eb. In this embodiment, the first section 218Ea includes structural fibers 224Ea dispersed in a first binding matrix 226Ea. The second section 218Eb is substantially devoid of structural fibers and may comprise a second binding matrix 226Eb (e.g., may consist essentially of the binding matrix 226Eb) that may be the same as or different than the epoxy resin of first binding matrix 226Ea. Alternatively, the second section 218Eb may be substantially devoid of any material, i.e., may be hollow through the length of the fiber-reinforced composite member 216E. In another characterization, the second section 218Eb may comprise a lightweight filler material, such as a polymer foam, to reduce the overall weight (e.g., weight per unit length) of the fiber-reinforced composite strength member 218Ea.

The fiber-reinforced composite strength members may also include other features in addition to the binding matrix and the structural fibers dispersed through the binding matrix, i.e., in addition to the fiber-reinforced composite materials described above. For example, the fiber-reinforced composite strength members may also include a material layer disposed around the outer surface of the binding resin matrix, e.g., a coating. The additional material layer may be selected to provide additional protection for the composite materials (e.g., the resin and/or the structural fibers), or may be selected to provide additional functionality to the composite strength member. The additional material layer may be a metal layer, a metal oxide layer, a glass layer or a polymer layer. In one configuration, the additional material layer is a polymer layer that is selected to provide protection for the fiber-reinforced composite materials, e.g., as a moisture barrier and/or as a dielectric layer. Such polymer layers may be disposed on the fiber-reinforced composite by methods such as dip coating, spray coating and the like, and may be applied during manufacture of the fiber-reinforced composite material or after manufacture of the composite material.

In the embodiment illustrated in FIG. 2F, the fiber-reinforced composite strength member 216F includes a fiber-reinforced composite section 218F that includes structural fibers 224F dispersed in a binding matrix 226F. The composite section 218F is surrounded by a material layer 222F. The material layer 222F may comprise a coating that is disposed around and substantially surrounds the composite section 218F. In one characterization, the composite material section 218F may include carbon structural fibers disposed in an epoxy resin matrix, and the material layer 222F may include a coating that is selected to protect the carbon fibers and the resin from degradation, such as a polymer coating or a metallic coating. Examples of fiber-reinforced composite members that include outer material layers are illustrated in U.S. Patent Publication No. 2007/0193767 by Guery et al. and U.S. Patent Publication No. 2012/0090892 by Meyer et al., each of which is incorporated herein by reference in its entirety. Further, such an outer material layer may be used in combination with any strength member configuration, e.g., any configuration illustrated in FIGS. 2A-2F.

The fiber-reinforced composite sections described above may have a relatively high fiber-to-resin ratio to provide sufficient properties (e.g., tensile strength) to the composite strength member. In one characterization, the fiber-reinforced composite sections include at least about 50 volume % fibers, such as at least about 60 volume % fibers.

In accordance with the products, methods and systems disclosed herein, the fiber-reinforced composite strength members may incorporate at least a first sensing optical fiber that is integrally disposed (e.g., fully disposed) within the structure of the fiber reinforced composite strength member. For example, a sensing optical fiber may be disposed between a fiber-reinforced composite section and an outer material layer that surrounds the fiber-reinforced composite section (e.g., see FIG. 2F).

In one particular characterization, a sensing optical fiber is disposed within the binding matrix along a length of the binding matrix, e.g., along substantially the entire length of the fiber-reinforced composite strength member. It is a particular advantage that the sensing optical fiber may be disposed under an outer material layer or may be fully disposed within the binding matrix, i.e., that the sensing optical fiber is not directly exposed to the exterior environment along its length. For example, by fully disposing the sensing optical fiber within the fiber-reinforced composite strength member, the sensing optical fiber is fully protected (e.g., shielded) from the exterior environment by the outer material layer and/or by the binding matrix, thereby ensuring that natural or man-made environmental factors (e.g., heat, impact stresses, etc. . . . ) will not significantly impair the performance of the sensing optical fiber. Further, particularly by disposing the sensing optical fiber within the binding matrix, the sensing optical fiber is physically and intimately bound to the matrix within a fiber-reinforced composite section, and forces that act upon the fiber-reinforced composite strength member (e.g., tensile strain) will be fully and consistently transmitted to the sensing optical fiber along the entire length of the fiber-reinforced composite strength member, ensuring highly accurate measurements, e.g., of stress and strain.

To enable the interrogation of a fiber-reinforced composite strength member and detect a condition of the fiber-reinforced composite strength member along its length, one or more sensing optical fibers may be disposed along a length of the composite strength member. FIG. 3A illustrates a partial cross-sectional view of a fiber-reinforced composite strength member which is similar in cross-sectional configuration to the fiber-reinforced composite strength member illustrated in FIG. 2B. The fiber-reinforced composite strength member 316A includes an inner section 318Aa and an outer section 318Ab that surrounds the inner section 318Aa. In one characterization, the inner section 318Aa includes a plurality of substantially continuous reinforcing carbon fibers in a binding matrix, and the outer section 318Ab is a fiber-reinforced composite section that includes a plurality of substantially continuous reinforcing glass fibers in a binding resin matrix, which may be the same or different than the binding matrix of the inner section 318Aa. For purposes of illustration, the outer section 318Ab is illustrated as being partially stripped away from the inner section 318Aa.

At least a first sensing optical fiber 328Aa is disposed within the fiber-reinforced composite strength member 316A. As illustrated in FIG. 3A, the first sensing optical fiber 328Aa is fully disposed within the binding matrix of the inner section 318Aa along a length of the fiber-reinforced composite strength member 316A. By “fully disposed,” it is meant that the sensing optical fiber 328Aa is completely surrounded by the binding matrix of the fiber-reinforced composite strength member 316A along the length that the sensing optical fiber 328Aa that is in contact with the fiber-reinforced composite strength member 316A. Thus, an end portion 330Aa of the sensing optical fiber 328Aa may extend beyond an end 332A of the fiber-reinforced composite strength member 316A, such as to allow operative coupling of the sensing optical fiber 328Aa to a light signal source (e.g., a laser) and/or to a signal detector, as is discussed below.

Further, the first sensing optical fiber 328Aa may be integrally formed within the binding matrix of the strength member 316A. That is, the first sensing optical fiber 328Aa may be in direct contact (e.g., with no intervening material layers) to facilitate mechanical coupling of the optical fiber 328Aa to the binding matrix.

The sensing optical fibers disclosed herein (e.g., the first sensing optical fiber 328Aa) are defined as cylindrical glass fibers that transmit light along their longitudinal axis by total internal reflection. The sensing optical fibers comprise a core and a cladding surrounding the core, where the refractive index of the core is greater than the refractive index of the cladding. Both the core and the cladding typically comprise a silica-based glass that is carefully doped with other elements (e.g., Ge, Al, F, B) to control the refractive index of the core and the cladding. Such sensing optical fibers may also be provided with a polymeric surrounding the fibers, such as a UV-cured coating.

The sensing optical fiber 328Aa may be a single-mode optical fiber. A single-mode optical fiber is configured to transmit a single ray of light (i.e., a single mode), and typically comprises a relatively small diameter core (e.g., 8 μm to 10.5 μm diameter) surrounded by a relatively thick cladding (e.g., a cladding diameter of about 125 μm). Alternatively, the sensing optical fiber 328Aa may be a multi-mode optical fiber. Multi-mode optical fibers are configured to transmit multiple rays of light (i.e., multiple modes) and, as compared to single-mode optical fibers, have a larger core diameter (e.g., 50 μm to 100 μm). In either case, the optical fibers may be provided in lengths of several kilometers or more, e.g., for incorporation into a fiber-reinforced composite member of several kilometers or more.

As illustrated in FIG. 3A, the first sensing optical fiber 328Aa is disposed substantially along a neutral axis 334A (i.e., a neutral bending axis) through the length of the fiber-reinforced composite strength member 316A. The neutral axis 334A is an axis through the cross-section of the fiber-reinforced composite strength member 316A along which there are substantially no longitudinal bending stresses or strains. For a symmetric composite strength member (i.e., a symmetric cross-sectional shape), the neutral axis will be the geometric centroid of the cross-section. As is discussed in more detail below, placement of at least a first sensing optical fiber 328Aa along a neutral axis 334A may advantageously reduce or eliminate the action of bending modes upon the sensing optical fiber 328Aa. As a result, the first sensing optical fiber 328Aa may be subjected only to tensile stresses, which can enable a more accurate measurement of those tensile stresses in the sensing optical fiber 328Aa, and hence in the fiber-reinforced composite strength member 316A, particularly when the first sensing optical fiber 328Aa is integrally formed with the binding matrix.

As illustrated in FIG. 3A, the fiber-reinforced composite strength member 316A also includes at least a second sensing optical fiber 328Ab that is fully disposed within the composite strength member 316A, e.g., is fully disposed within the binding matrix along a length of the fiber-reinforced composite strength member 316A. The above-described characteristics of the first sensing optical fiber 328Aa may be equally applicable to the second sensing optical fiber 328Ab. As illustrated in FIG. 3A, the second sensing optical fiber 328Ab is offset from the neutral axis 334A along the length of the fiber-reinforced composite strength member 316A, e.g., is offset from the first sensing optical fiber 328Aa. For example, the second sensing optical fiber 328Ab may be offset from the neutral axis 334A by at least about 1.5 mm, such as by at least about 2.0 mm. Stated another way, the second sensing optical fiber 328Ab may be placed proximate to an outer surface of the fiber-reinforced composite strength member 316A, e.g., within 0.5 mm of an outer surface of the fiber-reinforced composite strength member 316A.

Through the inclusion of at least two sensing optical fibers, one along a neutral axis 334A and one offset from the neutral axis 334A, various conditions of the fiber-reinforced composite strength member 316A may be accurately determined, such as by comparative analysis of the data obtained from the two sensing optical fibers 328Aa and 328Ab. It may be advantageous that the second sensing optical fiber 328Ab be disposed in substantially linear relation with the neutral axis (e.g., linear with the first sensing optical fiber 328Aa).

The second sensing optical fiber 328Ab may be the same or similar to the first sensing optical fiber 328Aa (e.g., both single-mode optical fibers or both multi-mode optical fibers). Alternatively, the sensing optical fibers may be of a different type. In one particular characterization, the first sensing optical fiber 328Aa is a single-mode optical fiber (e.g., configured for distributed sensing of tensile strain) and the second sensing optical fiber 328Ab is a multi-mode optical fiber (e.g., configured for distributed sensing of temperature). Alternatively, the first sensing optical fiber 328Aa may be a multi-mode optical fiber and the second sensing optical fiber 328Ab may be a single-mode optical fiber.

Additional sensing optical fibers may be incorporated into the fiber-reinforced composite strength member, e.g., disposed within the binding matrix, in addition to a first sensing optical fiber 328Aa and a second sensing optical fiber 328Ab. Such additional sensing optical fibers may be placed, for example, at different distances from the neutral axis 334A (e.g., distance along the cross-section) of the fiber-reinforced composite strength member 334A, including proximate to an outer surface of the fiber-reinforced composite member 334A. Such additional sensing optical fibers may enable the detection of additional conditions of the fiber-reinforced composite strength member 334A, and/or may provide redundancy, such as in the event that one or more of the other sensing optical fibers fails to function in its intended manner.

FIG. 3B illustrates another configuration of a fiber-reinforced composite strength member incorporating a sensing optical fiber along a length of the strength member. The fiber-reinforced composite strength member 316B includes a fiber-reinforced composite section 318B that is comprised of structural fibers (e.g., carbon fibers) and a binding matrix (e.g., a resin matrix). In the embodiment illustrated in FIG. 3B, the fiber-reinforced composite strength member 316B also includes a material layer 322B (e.g., a coating) disposed around the composite section 318B. (For purposes of illustration, the material layer 322B is illustrated as being partially removed from the composite section 318B). For example, the material layer 322B may be an insulative and durable polymer, such as polyether ether ketone (PEEK). Other polymers useful for the material layer 322B may include polytetrafluorothylene (PTFE), a fluorinated ethylene polymer (FEP) and polyoxymethylene (POM). The material layer 322B may also be a metal, such as aluminum. Further, more than one material layer may be disposed around the composite section 318B.

The fiber-reinforced composite strength member 316B includes a sensing optical fiber 328B that is disposed between the fiber-reinforced composite section 318B and the material layer 322B. In this manner, the material layer 322B may advantageously protect the sensing optical fiber 328B, as well as the composite section 318B, from the surrounding environment (e.g., moisture) and/or from impact damage. Placement of a sensing optical fiber 328B near (e.g., proximate) the outer circumference of the fiber-reinforced composite strength member 316B in this manner may enhance the ability of the sensing optical fiber 328B to more accurately detect an environmental condition (e.g., temperature) external to the fiber-reinforced composite strength member 316B. As with the configuration illustrated in FIG. 3A, the fiber-reinforced composite strength member 316B may include additional sensing optical fibers along its length, e.g., disposed within the binding matrix or disposed between the composite section 318B and the material layer 322B. For example, an additional sensing optical fiber may be disposed along a neutral axis of the composite strength member 316B, as is discussed above.

As is discussed above, the fiber-reinforced composite strength members include at least one sensing optical fiber disposed within the fiber-reinforced composite strength member, e.g., disposed within a binding resin matrix and/or disposed between a fiber-reinforced composite section and an outer material layer. The sensing optical fiber may be a long and continuous optical fiber that runs through substantially the entire length of the fiber-reinforced composite strength member. Further, as is discussed above, the fiber-reinforced composite strength member may include substantially continuous structural fibers, e.g., substantially continuous tows of the structural fibers. Such structures may be fabricated using a variety of methods, such as hand layups, tape placement or others. In one characterization, the fiber-reinforced composite strength member (e.g., the fiber-reinforced composite section) is at least partially manufactured by a pultrusion process.

The fiber-reinforced composite strength members are particularly configured for use in an overhead electrical cable, particularly for use in a high voltage overhead transmission line, e.g., a high voltage, an extra-high voltage (EHV) or an ultra-high voltage (UHV) overhead transmission line. In this regard, an electrically conductive layer may be disposed around an outer surface (e.g., an outer circumference) of the fiber-reinforced composite strength member, such as by stranding the strength member with individual strands of an electrically conductive material. FIG. 4 illustrates a perspective view of a cross-section of an overhead electrical cable 410 similar to that illustrated in FIG. 1. The overhead electrical cable 410 includes an elongate fiber-reinforced composite strength member 416 that extends for substantially the entire length of the overhead electrical cable 410. The strength member 416 is a fiber-reinforced composite strength member that may include one or more fiber types disposed in a resin matrix, as is discussed in detail above (see FIGS. 2A-2F). As illustrated in FIG. 4, the strength member 416 has a substantially circular cross-sectional shape. For use in overhead electrical cables, the single-element (e.g., single rod) strength member 416 may have an effective outer diameter of, for example, at least about 3 mm and not greater than about 15 mm, although the present disclosure is not limited to use with any specific diameter strength member.

A first sensing optical fiber 428a is disposed within the composite strength member 416 along a neutral axis thereof (e.g., in the geometric center of the circular cross-section), and a second sensing optical fiber 428b is disposed within the strength member 416 along an axis that is offset (e.g., spaced away) from the neutral axis. See FIG. 2(a). The sensing optical fibers 428a, 428b may be single-mode optical fibers or multi-mode optical fibers. In one configuration, the first sensing optical fiber 428a (i.e., disposed along a neutral axis) is configured to measure strain (e.g., tensile strain) along the length of the strength member 416 and is a single-mode optical fiber. In this configuration, the second sensing optical fiber 428b is configured to measure temperature and may be a multi-mode optical fiber. Such a configuration is discussed in more detail below.

The overhead electrical cable 410 also includes a first electrically conductive layer 412a disposed around the strength member 416. The electrically conductive layer 412a includes a plurality of strands of an electrically conductive material (e.g., conductive strand 414a) that are helically wound (e.g., stranded) around the strength member 416. As illustrated in FIG. 4, the overhead electrical cable 410 further includes a second electrically conductive layer 412b that also includes a plurality of strands of an electrically conductive material (e.g., strand 414b). It is to be appreciated that additional conductive layers may also be provided, as may be desirable for providing a higher cross-sectional area for increased electrical conduction (e.g., decreased resistivity) across the overhead electrical cable 410.

The electrically conductive layers 412a/412b may be fabricated from any electrically conductive material that is desired for a particular application, including copper, aluminum and alloys thereof. In one characterization, the electrically conductive layers 412a/412b include aluminum strands, particularly aluminum strands that are configured (e.g., sized) to carry high voltages, e.g., in excess of 100 kV. Various types of aluminum, including aluminum alloys, may be utilized for the conductive layers 412a/412b. In one characterization the conductive strands are fabricated from fully annealed aluminum, such as fully annealed 1350-0 aluminum. Fully annealed aluminum advantageously has relatively high conductivity, about 63% IACS (international annealed copper standard), and excellent thermal resistance properties for use in overhead electrical cables.

Further, the strands 414a/414b are non-circular strands (e.g., are polygonal in cross-section), and in one characterization are trapezoidal strands, i.e., have a trapezoidal-shaped cross-section. The use of trapezoidal-shaped strands advantageously enables more conductive material (e.g., a higher cross-sectional area of conductor) to be provided in an equivalent diameter configuration (e.g., diameter of the overhead electrical cable) as compared to round strands. Strands having other cross-sections may be utilized, such as those referred to as Z-WIRE strands available from Nexans (Paris, FR).

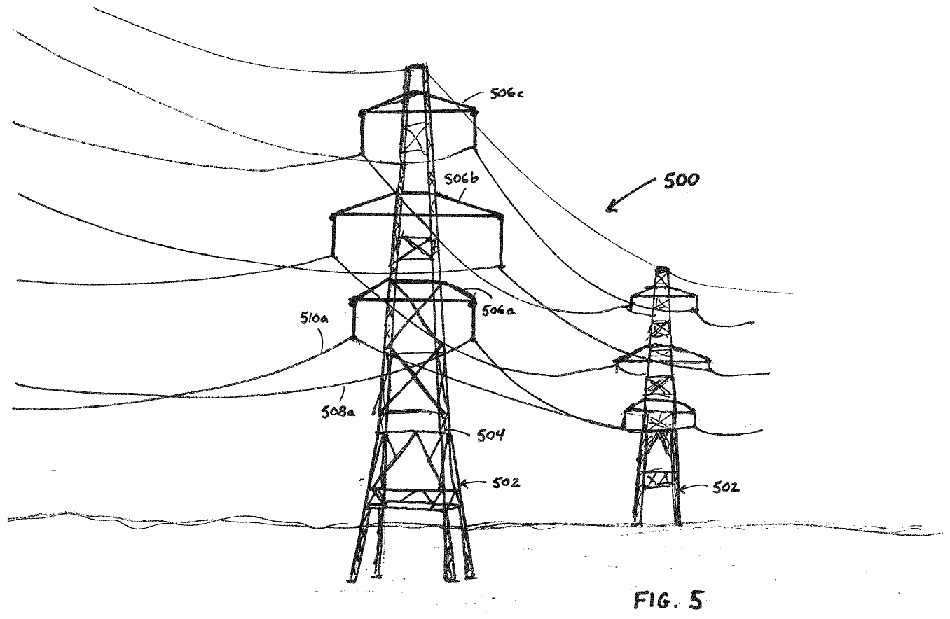

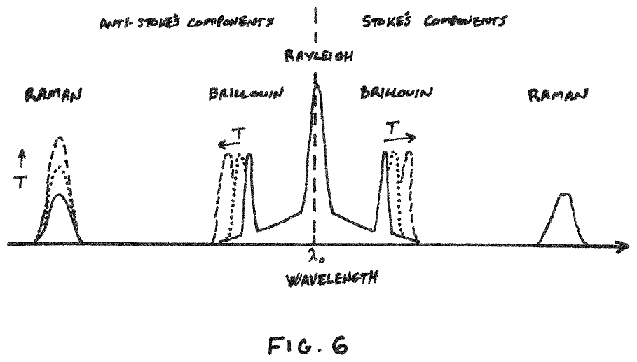

The overhead electrical cables including a fiber-reinforced composite strength member having sensing optical fiber(s) operatively disposed therethrough may be utilized in transmission lines that form the backbone of an electrical transmission grid. FIG. 5 illustrates a perspective view of a portion of a transmission line 500 forming part of an electrical transmission grid, e.g., by being interconnected to other transmission lines. The transmission line 500 includes a plurality of suspension towers 502 that are spaced-apart by a predetermined distance. The suspension towers 502 each include a vertical support section 504 that vertically elevates and supports a plurality of cross-arms 506a, 506b and 506c in vertically spaced-apart relation. Each of the cross-arms, in turn, supports at least one pair of overhead electrical cables (e.g., overhead electrical cables 508a and 510a) on opposite sides of the suspension tower 502 that are isolated from the suspension tower by electrical insulators (not illustrated). In a suspension tower 502 the insulators are typically in a vertical position or in a V-arrangement. Those of skill in the art will recognize that other configurations of suspension towers may be used, e.g., those supporting the overhead electrical cables in horizontally spaced-apart relation.

When the transmission line 500 is constructed, the overhead electrical cables are strung onto the suspension towers 502 and are pulled at a very high mechanical tension to ensure that the overhead electrical cables are elevated at a sufficient vertical distance above the ground or above any objects below the overhead electrical cables, e.g., above man-made objects such as buildings, roads, train tracks, or the like, or natural objects such as trees. The suspension towers are disposed between at least two dead-end towers (i.e., anchor towers) to which the ends of the overhead electrical cables may be anchored after pulling at high tension. As is known to those of skill in the art, dead-end towers are constructed to be stronger than suspension towers and may have a wider base and/or stronger attachment points for the overhead electrical cables. Dead-end towers are utilized where a transmission line ends, where the transmission line turns at a large angle, or on each side of a major crossing (e.g., a river or valley). Dead-end towers are also utilized at predetermined intervals (e.g., up to about 6 km) to divide the transmission line into segments. For example, a transmission line segment may include two dead-end towers and from about 6 to about 15 suspension towers between the two dead-end towers (e.g., at least about 1500 meters). This sectionalization of the transmission line into segments may prevent propagation of catastrophic faults beyond each section.

To enable the application of such high tensions in the electrical conductor, the fiber-reinforced composite strength members in the overhead electrical cables may be characterized as having a very high tensile strength, such as a tensile strength of at least about 1400 MPa, or even at least about 2000 MPa.

The fiber-reinforced composite strength members in overhead electrical cables may also have sufficient flexibility (e.g., modulus of elasticity) to be wound upon a storage spool for storage and/or transportation of the strength member to a stranding facility (e.g., where the strength member is wound with an electrically conductive layer to form an electrical conductor), and for transportation of the electrical conductor to the transmission line construction site.

Fiber-reinforced composite strength members that are configured for use in overhead electrical cables may also be characterized as having a length that is sufficient for the construction of a power transmission line 500, e.g., without requiring an undesirably large number of splices to connect discrete lengths of electrical conductors. In one characterization, the fiber-reinforced composite strength member (and the overhead electrical cable) has a continuous length of at least about 500 meters, such as at least about 1 km, at least about 2 km, at least about 3 km or even at least about 5 km. As a practical matter, the length of the fiber-reinforced composite strength member and the overhead electrical cable will typically not exceed about 10 km.

Examples of overhead electrical cables including a fiber-reinforced composite strength member are described in U.S. Pat. No. 7,211,319 by Hiel et al. and U.S. Pat. No. 7,368,162 by Hiel et al., each of which is incorporated herein by reference in its entirety.

As is discussed above, the fiber-reinforced composite strength member of the overhead electrical cables disclosed herein includes at least a first sensing optical fiber disposed therein and may include two or more sensing optical fibers disposed therein. These sensing optical fibers may be components of a sensor system that is configured for interrogating the fiber-reinforced composite strength member to detect a condition of the fiber-reinforced composite strength member. Examples of fiber-reinforced composite strength member conditions that may be determined using the disclosed sensor systems include strain (e.g., tensile strain), temperature and length of the fiber-reinforced composite strength member. From one or more of these conditions, a state of the fiber-reinforced composite strength member and of the electrical conductor may be determined, such as line sag, the presence of a defect, electrical current and the like.

It is an advantage of the configurations disclosed herein that the sensing optical fiber(s) are disposed within (e.g., are integral with) the fiber-reinforced composite strength member. In this manner, the temperature, strain and other conditions of the sensing optical fiber(s) will be strongly correlated to the conditions actually experienced by the fiber-reinforced composite strength member and the overhead electrical cable. For example, the tensile strain experienced by the fiber-reinforced composite strength member will be substantially identical to the tensile strain experienced by the sensing optical fiber, since the sensing optical fiber will be strained to the same degree as the composite material (e.g., as the binding matrix) when a force acts upon the composite strength member. Stated another way, the sensing optical fiber is directly and intimately bonded to the fiber-reinforced composite member (e.g., to the binding matrix) such that the sensing optical fiber is subjected to the same conditions as the fiber-reinforced composite member. Further, the binding matrix will protect the sensing optical fiber from environmental influences that might otherwise damage the sensing optical fiber, including during manufacture of the overhead electrical cable (e.g., stranding) and installation of the overhead electrical cable.

In one characterization, the sensor system is configured as a distributed fiber optic sensor system. A distributed sensor system utilizes the sensing optical fiber as a linear sensor that may determine a condition of the fiber-reinforced composite strength member at any position along the length of the fiber-reinforced composite strength member. That is, a distributed sensor may determine both a condition and the location of that condition along the length of the fiber-reinforced composite strength member with a reasonably high degree of accuracy. Distributed sensor systems offer the unique characteristic of being able to determine conditions along the entire length of the sensing optical fiber, even when the sensing optical fiber is several kilometers or more in length, and without requiring any specialized sensor structures (e.g., Bragg gratings) to be placed along the length of the composite strength member.

The distributed fiber optic sensor systems may include a coherent light source (e.g., a pump laser source) that is operatively coupled to the sensing optical fiber to enable the light to be passed (e.g., pulsed) into the optical fiber in a controlled manner. The light source is configured to send a signal (e.g., a pulse) down the sensing optical fiber, and the detection (e.g., the measurement) of the condition in the fiber is performed by analyzing light that is backscattered by the optical fiber sensor. In this regard, the sensor system may also include a signal detector such as an interferometer, that is configured to detect the backscattered light signals.

Referring to FIG. 6, the components of the backscattered light can be categorized as Rayleigh components, Brillouin components and Raman components. The backscattered Rayleigh components have the same frequency (i.e., same wavelength) as the primary light source and have a relatively high intensity. The Rayleigh components of the backscattered light signal can be analyzed to determine the length of the sensing optical fiber by using Optical Time Domain Reflectometry (OTDR). Thus, Rayleigh components may be used to detect a break in the optical fiber indicating possible damage to the conductor cable. However, the Rayleigh components are not capable of providing any further significant information about the conditions of the sensing optical fiber.

In one characterization, the distributed fiber optic sensor system is based on (e.g., implements) the analysis of at least one of Raman backscattered light components (e.g., a Raman distributed sensor) and Brillouin backscattered light components (e.g., a Brillouin distributed sensor). Both Raman and Brillouin distributed sensor systems make use of a non-linear interaction between the primary light signal and the sensing optical fiber material. When a primary light signal of known wavelength (λₒ) is input to an optical fiber, a very small amount of the light signal is scattered back (e.g., a backscattered light signal) at every point along the sensing optical fiber. The back scattered light contains shifted components at wavelengths that are different than the primary light signal. Light components that are shifted to a longer wavelength (i.e., lower energy) are referred to as Stokes components, whereas light components that are shifted to a shorter wavelength (i.e., higher energy) are referred to as Anti-Stokes components. See FIG. 6. These shifted backscattered light components can be detected and analyzed to ascertain information about the local conditions of the sensing optical fiber, such as its strain and temperature at different points along the length of sensing optical fiber.

In one configuration, at least one of the sensing optical fibers is a component of a Raman distributed temperature sensor. In a Raman distributed temperature sensor, the interaction between the primary light signal (e.g., the pump laser signal) and optical phonons in the sensing optical fiber material (e.g., silica) creates two backscattered light components in the backscattered light spectrum, Raman Stokes and Raman anti-Stokes. As is illustrated in FIG. 6, the Raman anti-Stokes component is temperature dependent, i.e., the intensity of the Raman anti-Stokes component increases with increasing temperature of the sensing optical fiber. As a result, the relative intensity of the Raman Stokes and the Raman anti-Stokes backscattered light components can be measured and used to determine a temperature of the sensing optical fiber. The Raman Stokes and Raman anti-Stokes backscattered light components can be detected by a signal detector such as an interferometer or a dispersive spectrometer, for example.

The position of the temperature reading along the length of the sensing optical fiber can also be determined from the Raman backscattered light components. When a pulsed light signal (e.g., of several nanoseconds in duration) is used to interrogate the sensing optical fiber, the back-scattered intensity of the Raman Stokes and Raman anti-Stokes backscattered light components can be recorded as a function of time (e.g., “round trip” time), making it possible to obtain a temperature profile along the length of the sensing optical fiber, i.e., along the length of the fiber-reinforced composite strength member.

In one characterization, the sensor system incorporated into the fiber-reinforced composite strength member includes a Raman distributed temperature sensor having a multi-mode sensing optical fiber. The multi-mode sensing optical fiber having a high numeric aperture may increase the intensity of the backscattered light which can be important due to the relatively low magnitude of the Raman backscattered light signals.

Examples of Raman distributed temperatures sensors include those available from Sensa (Southampton, UK), the DiTemp system available from Smartec (Switzerland) and Sensortran (Austin, Tex., USA).

In one configuration, at least one of the sensing optical fibers is a component of a Brillouin distributed sensor system. Brillouin distributed sensors utilize Brillouin backscattering, which is the result of an interaction between the primary light signal and time dependent optical density variations within the optical fiber (i.e., acoustic phonons). The acoustic phonons create a periodic modulation of the refractive index (e.g., the optical density) of the sensing optical fiber material. Brillouin scattering occurs when the propagating primary light signal is diffracted back by this moving “grating”, resulting in a frequency (and wavelength) shifted component in the backscattered light signal (i.e., spontaneous Brillouin scattering).

As is illustrated in FIG. 6, as the temperature of the sensing optical fiber increases, the wavelength of the Brillouin backscattered components shifts further away from the primary wavelength λₒ. This wavelength shift can be utilized to determine a temperature of the sensing optical fiber. As with a Raman distributed temperature sensor, the location of the temperature along the length of the sensing optical fiber can also be determined using time of flight information for the backscattered light signal.

Unlike Raman distributed sensors, Brillouin distributed sensors may also be utilized to detect the strain (e.g., tensile strain) in the sensing optical fiber. That is, a change in the strain within the sensing optical fiber also causes a wavelength shift in the Brillouin backscattered light components due to a change in optical density of the sensing optical fiber. As a result, the strain that is experienced by the sensing optical fiber, and hence by the composite strength member, at any point along its length can be determined.

Brillouin distributed sensors may be configured to implement a spontaneous Brillouin-based technique, i.e., Brillouin optical time domain reflectometry (BOTDR), or a stimulated Brillouin based technique, i.e., Brillouin optical time domain analysis (BOTDA). One advantage of a BOTDR configuration is that a single coherent pump light source can be utilized (i.e., at one end of the sensing optical fiber). BOTDR also offers the capability of simultaneously measuring the temperature and strain in the sensing optical fiber. However, the detected backscattered light signal is typically very weak, requiring signal processing and a long integration time.

In another configuration, the Brillouin distributed sensor system implements a BOTDA technique. In BOTDA, a counter-propagating input light signal (sometimes referred to as a “probe” signal or a “counter wave” signal) having a wavelength difference that is equal to the Brillouin shift is used. This probe signal reinforces the phonon population in the sensing optical fiber, resulting in a higher signal-to-noise ratio. When the primary (pump) light signal is a short pulse, and its reflected intensity is analyzed in terms of flight time and wavelength shift, it is possible to obtain a profile of the Brillouin shift along the length of the sensing optical fiber. BOTDA techniques generally require the two counter propagating light signal wavelengths to be very stable (e.g., synchronized laser sources). Advantageously, a temperature resolution of less than 1.0° C. or even less than 0.5° C. may be achieved. Further, very small strain shifts experienced by the sensing optical fiber may be detected.

Thus, a Brillouin distributed sensor is useful for temperature monitoring, and is uniquely suited for strain measurement. In this regard, it is typically necessary to know the wavelength shift in the sensing optical fiber at a reference temperature in order to calculate the absolute temperature at any point along the sensing optical fiber(s). It is also typically necessary to know the wavelength shift of the unstrained fiber in order to enable an absolute strain measurement.

Examples of Brillouin distributed sensors for strain and/or temperature measurement are disclosed in U.S. Pat. Nos. 7,499,151 and 7,599,047, each of which is incorporated herein by reference in its entirety. Examples of Brillouin distributed sensors are available from Oz Optics (Ottawa, ON, Canada) and Omnisens (Morges, Switzerland), for example.

In one particularly advantageous characterization, the effect of temperature changes on the fiber strain within the fiber-reinforced composite strength member is accounted for by utilizing both a multi-mode sensing optical fiber (e.g., in a Raman distributed temperature sensor) and a single-mode sensing optical fiber (e.g., in a Brillouin distributed strain sensor). The strain calculation may then advantageously include separating out the temperature effect on strain using the temperature that is detected by the Raman distributed temperature sensor system.

In another characterization, the overall length of the fiber-reinforced composite member may be determined by measuring the overall length of the sensing optical fiber. This length information may be measured using the sensing optical fiber, using either Rayleigh backscattering, Raman backscattering and/or Brillouin (OTDR) backscattering.

Thus, to ensure the overhead electrical cable performance when using a fiber-reinforced composite member as the strength member, it is highly desirable to ensure that the structural fibers are not excessively fractured, as fractured structural fibers will decrease tensile strength, and the overhead electrical cable could fail (e.g., break) if insufficient continuous structural fibers remain to support the tension load on the overhead electrical cable. The system disclosed herein may advantageously enable the detection of such fractures, either before, during or after installation of the overhead electrical cable.

In one characterization, the integrity of the fiber-reinforced composite strength member may be interrogated by a distributed sensor system prior to stranding the strength member with a conductive layer(s). For example, a strength member that is wrapped around a storage spool may be interrogated using a distributed fiber optic sensor to identify defects (e.g., manufacturing defects) in the strength member. In one characterization, the strength member is interrogated using Brillouin distributed sensor (e.g., BOTDR or BOTDA) to detect the strain along the length of the strength member. Any abnormalities in the strain along its length may be indicative of a defect within the strength member, such as a crack or a void within the binding matrix.

Such a method may advantageously be used to rapidly determine if a manufacturing defect is present in the strength member before further manufacture (e.g., stranding) of the electrical conductor occurs, thereby avoiding wasted time and cost. The distributed sensor systems described herein may also locate the defect along the length of the strength member, which may be several kilometers or more in length, so that a determination can be made as to whether or not to salvage one or more portions of the strength member that do not include the defect.

In another characterization, the integrity of the fiber-reinforced composite strength member may be interrogated after stranding the strength member with a conductive layer to form the electrical conductor and before installation of the overhead electrical cable. An improper stranding operation may place undue stresses on the fiber-reinforced composite strength member, causing undesirable defects (e.g., cracks) that weaken or otherwise compromise the integrity of the strength member.

In another characterization, the integrity of the strength member may be interrogated after installation of the overhead electrical cable, but before energizing (e.g., powering) the overhead electrical cable. In this manner, the transmission line operator may be assured that the overhead electrical cable does not contain any substantial defects due to manufacturing, improper stranding or improper construction of the transmission line.

The foregoing interrogation methods of the strength member may be performed in a discrete step, i.e., to provide information about the core integrity at a particular moment in time. Such information may be useful for manufacturers and installers of the overhead electrical cable to provide assurances to the transmission line operator that the integrity of the overhead electrical cable has not been compromised.

In one implementation, the properties of the fiber-reinforced composite strength member, and hence the properties of the overhead electrical cable, may be interrogated (e.g., monitored) in real time after energizing and during operation of the transmission line, e.g., during operation of the transmission grid. The real time interrogation of the transmission line may provide several benefits. For example, failures of the transmission line, including the location of the failure, may be detected almost immediately so that emergency action (e.g., line repair or diversion of electricity transmission) may be taken if needed. Further, data, e.g., representing temperature and/or strain fluctuations in the overhead electrical cable, and the location of those fluctuations, may be collected over time to assist in identifying potential points of failure before those failures occur. In addition, the data may be used to make real time adjustments to the operation of the power transmission grid that includes the transmission line, such as by reducing or increasing the amount of power that is being transmitted by the transmission line and/or by other transmission lines within the transmission grid.

While the primary function of the overhead electrical cables is to transfer electrical load, the electrical conductors must also be strong enough to support their own weight as well as any other weight (or stress) caused by ice, wind or other environmental factors. When the overhead electrical cable is installed (e.g., strung on suspension towers as illustrated in FIG. 5), the strength member supports the conductive layer(s) and bears substantially the entire tensile load that is placed on the electrical conductor. In addition to the loads resulting from other environmental factors. Such loads may cause the electrical conductor to sag, i.e., for the electrical conductor to stretch and drop closer to the ground, potentially creating hazardous conditions and possibly even causing a catastrophic failure of the transmission line.

For an overhead electrical cable, information that is indicative of the electrical conductor sag (e.g., in real time during operation of the transmission line) may be derived from the Brillouin distributed sensor output (e.g., a combined effect of temperature and tensile strength). This can also assist in the study and monitoring of ice formation (e.g., through tensile strain changes) and temperature changes as detected using the sensing optical fiber(s).

Sag in the overhead electrical cable may also be determined, wholly or in part, by directly measuring the length of the sensing optical fiber. The length may be measured, for example, using OTDR techniques measuring the Rayleigh backscattered light signal, the Raman backscattered light signal, or the Brillouin backscattered light signal.

In an overhead electrical cable, it is also desirable to determine the temperature of the electrical conductor and the location of the temperature reading. For example, damage to the outer electrically conductive layer (e.g., from gunshot) may reduce the cross-sectional area and result in a “hot-spot” where the operating temperature is elevated, possibly high enough to do permanent damage to the overhead electrical cable and cause an outage. In one characterization described above, the strength member includes a Raman distributed temperature sensor having a multi-mode optical fiber that is offset from the neutral axis of the strength member, i.e., is closer to an outer surface of the strength member. Such a configuration may advantageously enable a highly accurate reading of the temperature of the electrical conductor (e.g., of the conductive layer) due to the proximity of the multi-mode optical fiber to the conductive layer.

In an overhead electrical cable, the distributed temperature data may also provide valuable information about electrical conductor heating from the electrical load, including identification of local ‘hot spots’ for maintenance action described above, and for estimating the remaining life of the overhead electrical cable by collecting and analyzing data representative of its accumulated thermal exposure over time. The distributed strain data may also provide valuable information about the condition of the electrical conductor, including conductor tension, to ensure safe operation of the electrical conductor and the supporting structures. The combined conductor tension and temperature information (e.g., in real time along the entire length of the electrical conductor) may advantageously enable the utility operator to determine the electrical current flowing in the overhead electrical cable (e.g., in real time), and may alert the operators with sufficient warning time to deal with emergency conditions before they cause serious and/or wider outages.

As is described above with respect to FIG. 5, a transmission line may be divided into segments, e.g., segments defined by dead-end towers at opposite ends of an overhead electrical cable to which the overhead electrical cable is anchored. The overhead electrical cable(s) may be suspended between the two dead-end towers by one or more suspension towers. Advantageously, the overhead electrical cable anchored to first and second dead-end towers may be substantially continuous, i.e., not include any electrical splices along its length. A laser source (e.g., a first pump laser source) may be operatively supported by the first dead-end tower and may be configured to direct a light signal (e.g., a laser signal pulse) into a first end of at least a first sensing optical fiber in a first overhead electrical cable. In one characterization, a single laser source may be configured (e.g., through a beam splitter) to direct a laser pulse simultaneously down a plurality of sensing optical fibers disposed in a plurality of overhead electrical cables. Further, the overhead electrical cable(s) may be anchored to the dead-end towers by a dead-end fitting, and the laser source may be integrally formed with one or more of the dead-end fittings. Examples of such dead-end fittings are disclosed, for example, in U.S. Pat. No. 7,019,217 by Bryant and U.S. Pat. No. 8,022,301 by Bryant et al., each of which is incorporated herein by reference in its entirety.

One or more signal detectors (e.g., as described above) may also be operatively supported by the first dead tower. The signal detector(s) may be integrally formed with dead-end fittings, for example. Alternatively, or in addition to being supported by the first dead-end tower, a signal detector may be supported by a second dead-end tower at an opposite end of the overhead electrical cable from the laser source.

In another characterization, the sensor system(s) may be controlled and/or the data from the sensor system(s) may be collected remotely, e.g., at a central location that is not proximate the actual sensor systems. Such a centralized location may perform such control and collection for a plurality of locations along a single transmission line, and/or from a plurality of transmission lines within the electrical transmission grid. For example, the sensor system may be operatively coupled to a wireless transmission device (e.g., operatively mounted on a dead-end tower) so that control signals may be provided to the sensor systems and/or data may be remotely collected from the sensor systems. The sensor systems may also be powered using renewable and/or self-contained energy (e.g., solar panels), and the power source is preferably decoupled from the transmission line to ensure continued operation of the sensor systems during a power outage.

In addition to the use of the fiber-reinforced composite members and sensor systems described herein for overhead electrical cables in a transmission line, the fiber-reinforced composite members and systems may also be implemented in other components of a transmission line. For example, the fiber-reinforced composite members and systems may be used in the support towers (see FIG. 5) that vertically support the overhead electrical cables, and particularly may be used in the cross-arms of the support towers. In this regard, the support arms may be subject to varying loads as a result of varying environmental conditions (e.g., icing, wind, etc.) experienced by the transmission line. Thus, the condition of the cross-arm (e.g., the strain in the cross-arm) may be detected and that information may be used to determine the overall condition of the transmission line. Other components of the tower (e.g., the framing of the vertical support tower of FIG. 5) may also implement the fiber-reinforced composite members and systems disclosed herein to provide useful information regarding the condition of the transmission line.

By incorporating one or more of the foregoing implementations of a strength member for an overhead electrical cable and/or for other components of a transmission line that include sensor systems (e.g., distributed sensor systems), a system and method for the intelligent operation of a transmission line and/or a transmission grid comprising a plurality of transmission lines may be provided. Such a system and method may include the continuous or semi-continuous interrogation of the overhead electrical cables to detect, for example, temperature conditions, strain conditions, mechanical load and/or elongation of the overhead electrical cables, and taking action in response to certain identified conditions. From a determination of these conditions, other conditions and/or states may be determined, such as the sag of a particular conductor segment or the electrical current carried by a conductor segment.

For example, the action may include increasing or decreasing the power supplied to one transmission line. In one characterization, a distributed sensor detects an elevated temperature at a location on a transmission line, and an action is taken in response to the detection. For example, the response may include a precautionary action such as reducing the power transmitted over that transmission line, and/or a repair action such as dispatching a repair crew to investigate and repair the problem. In this regard, the distributed sensor systems advantageously enable the location of the problem to be determined with a high degree of accuracy (e.g., within several meters or less), thereby reducing the time necessary for the repair crew to locate the problem.

In another example, the tension (e.g., strain) being placed on the overhead conductor is measured, and remedial action can be taken if the measured strain is deemed to present a risk. In yet another example, the sag (e.g., due to thermal load, ice or wind) is calculated such as by measuring the elongation of the electrical conductor. If the amount of sag is determined to be a risk, remedial action can be taken to reduce the sag or to reduce the power being provided to the transmission line before the overhead electrical cable sags to a dangerous level.

As is discussed above, one problem that has been identified with respect to the interrogation of overhead electrical cables using sensing optical fibers is that it is extremely difficult to selectively access the sensing fibers from within the composite strength member and to make a reliable connection between the sensing optical fibers and the OTDR device. That is, the sensing optical fibers have a relatively small diameter, and are difficult to locate and connect to when they are disposed within the same matrix as the structural fibers. This problem is particularly difficult in the context of overhead electrical cable installations because the connections must be made in the field by technicians, often under difficult environmental conditions.

According to certain embodiments of the present disclosure, systems and methods to connect an interrogation device (e.g., an OTDR device) to the sensing optical fibers is disclosed. One system and method includes providing loose (e.g., unbound by a binding matrix) structural fibers and optical sensing fibers at the ends of the composite strength member during the manufacturing process, and installing sensing fiber connectors to the optical fibers. Another system and method includes cutting the composite strength member (e.g., during installation of the overhead electrical cable) and polishing the end of the strength member, including the optical fibers, to form a smooth surface including the end(s) of the optical fiber(s), and connecting the optical fibers to the interrogation device through a special alignment device. Another system and method includes cutting the composite strength member (e.g., during installation of the overhead electrical cable) and immersing the end of the strength member into a chemical solution that is selected to dissolve the binding matrix and then connecting the optical fibers to the interrogation device. Another method includes cutting the composite strength member (e.g., during installation of the overhead electrical cable), and using a specially designed torch to burn off the matrix, and then connecting the optical fibers to the interrogation device.

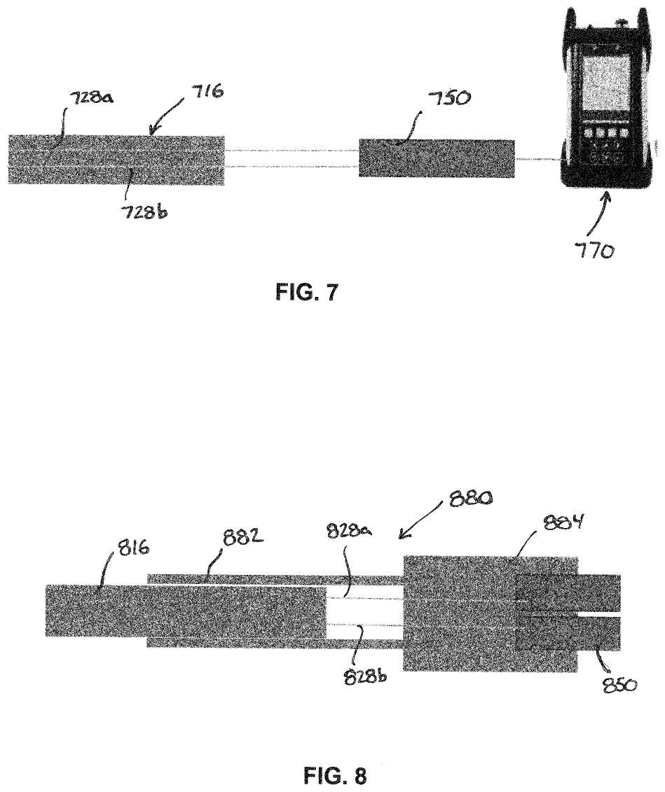

FIG. 7 schematically illustrates a connection system for coupling optical fibers from a composite strength member to an interrogation device. As illustrated in FIG. 7, this includes an interrogation device 770, e.g., an OTDR device. A connector 750 operatively links the interrogation device 770 to optical fibers 728a/728b. As illustrated in FIG. 7, the optical fibers 728a/728b extend beyond the end of the composite strength member 716. For example, the optical fibers may extend beyond the end of the strength member by at least about 3 cm, such as by at least about 5 cm, such as by at least about 9 cm. In another characterization, the optical fiber extends beyond the end of the strength member by not greater than about 40 cm, such as by not greater than about 30 cm. The composite strength member itself may have a length of at least about 500 meters, such as at least about 1000 meters, at least about 2000 meters, or even at least about 5000 meters.

Although illustrated as including two optical fibers, it will be appreciated that the system may include a single optical fiber, or a plurality of optical fibers, including 3 optical fibers, 4 optical fibers, 5 optical fibers, or more.

In one embodiment, the manufacturing process is controlled such that at least one end of the composite strength member includes loose fibers, e.g., structural fibers and optical fiber(s) that are not bound by a binding matrix. That is, the composite strength member is initially produced with loose fibers extending from at least one end of the composite strength member. When the composite strength member is fabricated in this manner, the optical fibers extending from the end may be damaged during handling (e.g., transportation) of the strength member.

As illustrated in FIG. 8, an arrangement for protecting the optical fibers and for facilitating connection of the optical fibers to an interrogation device is illustrated. The arrangement 880 includes a sleeve 882 having an aperture for receiving and end of the composite strength member 816 within the sleeve. To protect the optical fibers 828a and 828b, the sleeve may be fabricated from a rigid material such as a metal or a hard plastic material. The opposite end of the sleeve 882 is closed off by a case, which also receives the optical fibers 828a/828b within the case, which also secures a connector 850. The ends of the optical fibers 828a/828b are coupled to the connector 850 that is configured to link the optical fibers 828a/828b to an interrogation device. Both the strength member 816 and the connector 850 are fixed at the ends of the arrangement 880 so that the optical fibers 828a/828b are not subjected to potential damage during handling and transportation of the strength member 816.

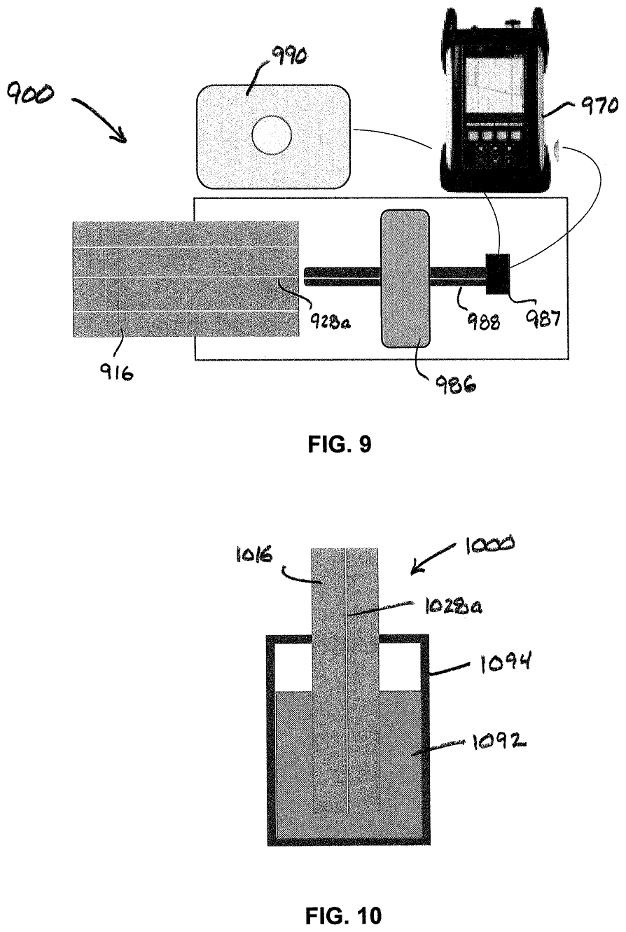

In another embodiment, the end of the composite strength member, including the end of the optical fiber(s), may be polished to form a smooth surface. Because the OTDR requires a very clean connection to the optical fibers, it will typically be necessary to polish the end of the strength member with a polishing pad having a grit size of about 1 μm or less. For example, the polishing may include multiple polishing steps using progressively smaller polishing grits down to a grit size of less than or equal to 0.5 μm or even less than or equal to 0.2 μm. Thereafter, the strength member including the optical fiber(s) may be attached to a fiber alignment apparatus. One embodiment of such a fiber-alignment apparatus is illustrated in FIG. 9. The apparatus 900 includes a 3-D stage 986 (e.g., capable of controlled movement in the x-axis, y-axis and z-axis) to move a fiber probe 988 until the fiber probe 988 aligns with at least one of the optical fiber(s) 928a. The movement of the 3D stage 986 may be manually controlled with the assistance of a viewing screen 990 through which an operator may be able to visually identify the optical fiber(s) 928a. An example of a 3D stage that may be useful for this purpose is the XYZ-LSMA-167 Stage available from IntelLiDrives Inc. of Philadelphia, Pa., USA.

After alignment between the fiber probe 988 and the optical fiber(s) 928a is achieved, the interrogation device 970 may be activated. As illustrated in FIG. 9, the apparatus 900 also includes a light guiding device 987 that is configured to split the light (e.g., the laser beam) into two distinct beams. One of the beams is routed to the viewing screen 990 for aligning the fiber probe 988 with the optical fiber(s) 928a. The other beam is directed to the OTDR 970 for carrying out a measurement, e.g., temperature, stress, strain, etc. The light guiding device 987 may comprise a fiber splitter, an optical switch, a MEMS (micro-electromechanical system), a collimator with a prism mirror that splits the light, or a reflective collimator.

The operation of the apparatus 900 may include the following steps. First, the fiber probe 988 is moved using the 3-D precision stage 986 to locate an optical fiber 928a in the core. The stage 986 is adjusted to align the probe 988 with the fiber 928a and to establish the proper distance between the probe 988 and the end of the optical fiber 928a. Movement of the probe 988 may be assisted by visually observing the fiber image in the viewing screen 990. If the light guiding device 987 splits the light, an OTDR measurement may be carried out. If the light guiding device 987 operates by deviating the light, such as with an optical switch, a change to the light direction toward the OTDR 970 will be necessary to carry out a measurement.

Another method disclosed herein includes exposure of the optical fibers at an end of the composite strength member by dissolution of the binding matrix with a chemical solvent. As illustrated in FIG. 10, a composite strength member 1016 including sensing optical fiber(s) 1028a may be cut at a desired location based the requirement of conductor stranding and/or overhead cable installation. One end of the composite strength member 1016 may be inserted into a container 1092 holding a chemical solvent that is selected to dissolve the binding matrix without dissolving the optical fiber 1028a. Examples of such chemical solvents include acids. After dissolution (e.g., removal) of the matrix, the sensing optical fiber 1028a may be located for linking to an interrogation device.

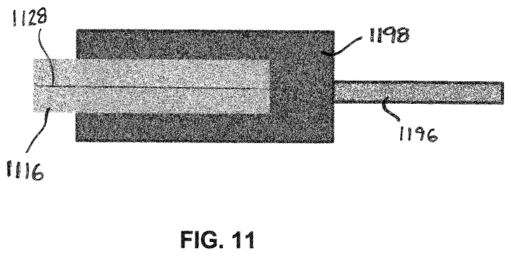

Another method for the removal of the matrix to expose the optical fibers is illustrated in FIG. 11. The composite strength member 1116 including an optical fiber 1128 may be cut at a desired location based the requirement of the stranding operation and/or overhead cable installation. One end of the strength member 1116 is inserted into a torch apparatus that includes a gas supply tube 1196 that is configured to supply gas to a torch 1198. The binding matrix may be burned off by the torch 1198 to expose loose fibers, including the optical fiber 1128.

In any of the foregoing embodiments for the removal of the matrix to expose the optical fibers, a coating may be applied to the exposed portion of the optical fibers to protect the fibers from damage. For example, the coating may be a polymer coating.

Further, in any of the foregoing embodiments, the optical fiber(s) may be colored, e.g., using pigments, dyes or the like, to facilitate location of the optical fibers relative to the non-optical fibers, e.g., the reinforcing fibers.

While various embodiments have been described and characterized in detail, it is apparent that modifications and adaptations of those embodiments will occur to those skilled in the art. It is to be expressly understood that these and other such modifications and adaptations are within the spirit and scope of the present disclosure.

What is claimed is:

1. A fiber-reinforced composite strength member configured for use in an overhead electrical cable and having a first composite end and a second composite end, the strength member comprising:
a binding matrix;
a plurality of reinforcing fibers operatively disposed within the binding matrix to form a fiber-reinforced composite section;
at least a first optical fiber disposed within the fiber-reinforced composite section and along a length of the strength member
wherein a first portion of the at least first optical fiber extends beyond at least one end of the fiber-reinforced composite strength member.

2. The fiber-reinforced composite strength member recited in claim 1, wherein the distance that the first optical fiber portion extends beyond the one end of the strength member is at least about 5 cm.

3. The fiber-reinforced composite strength member recited in any one of claim 1 or 2, wherein the distance that the first optical fiber portion extends beyond the one end of the strength member is not greater than about 40 cm.

4. The fiber-reinforced composite strength member recited in any one of claims 1 to 3, wherein a second portion of the first optical fiber extends beyond a second end of the strength member.

5. The fiber-reinforced composite strength member recited in any one of claims 1 to 4, wherein the first optical fiber is disposed near an outer circumferential surface of the strength member.

6. The fiber-reinforced composite strength member recited in any one of claims 1 to 5, wherein the strength member includes at least a second optical fiber element embedded in the binding matrix and extending along the length of the composite strength member, and wherein a first portion of the second optical fiber element extends a distance beyond the one end of the fiber-reinforced composite strength member.

7. The fiber-reinforced composite strength member recited in any one of claims 1 to 6, wherein the first optical fiber is selected from a single mode optical fiber, a multi-mode optical fiber and a low macro-bend loss optical fiber.

8. The fiber-reinforced composite strength member recited in any one of claims 1 to 7, wherein the strength member has a length of at least about 500 meters.

9. The fiber-reinforced composite strength member recited in any one of claims 1 to 8, wherein the strength member is wound upon a spool.

10. The fiber-reinforced composite strength member recited in any one of claims 1 to 9, further comprising a protective tube disposed around the first portion of the first optical fiber to protect the first portion from damage.

11. The fiber-reinforced composite strength member recited in claim 10, wherein the protective tube is fabricated from a metallic material or a hard plastic material.

12. An overhead electrical conductor comprising a strength member as recited in any one of claims 1 to 11, and a conductive layer wrapped around the strength member.

13. The overhead electrical conductor recited in claim 12, wherein the overhead electrical conductor is strung upon a plurality of support towers.

14. A method for the manufacture of a fiber-reinforced composite strength member configured for use in an overhead electrical cable, comprising the steps of:
pulling a first type of substantially continuous reinforcing fibers from a first reinforcing fiber spool;
pulling a first substantially continuous optical fiber from an optical fiber spool;
intermingling the first reinforcing fibers and the first optical fiber to form a fiber bundle;
impregnating the fiber bundle with a resin to form a resin-impregnated fiber bundle, wherein a leading portion of the fiber bundle is not impregnated with the resin;
forming the resin-impregnated fiber bundle into a cylindrically-shaped fiber bundle;
curing the cylindrically-shaped fiber bundle form a cured fiber-reinforced composite strength member; and
removing a portion of the first reinforcing fibers from the leading portion of the fiber bundle to substantially isolate the first optical fiber.

15. The method recited in claim 14, further comprising the step of pulling a second substantially continuous optical fiber from a second optical fiber spool.

16. The method recited in any one of claim 14 or 5615 wherein the intermingling step places the first optical fiber near a circumferential outer surface of the fiber bundle.

17. The method recited in any one of claims 14 to 16, wherein the reinforcing fibers comprise carbon fibers.

18. The method recited in any one of claims 14 to 17, wherein the first optical fiber is colored.

19. The method recited in any one of claims 14 to 18, further comprising the step of placing a protective tube over the isolated first optical fiber.

20. A system for detecting a condition of a fiber-reinforced composite strength member configured for use in an overhead electrical cable and having a first composite end and a second composite end, the system comprising:
a fiber-reinforced composite strength member comprising;
binding matrix,
a plurality of reinforcing fibers operatively disposed within the binding matrix to form a fiber-reinforced composite section,
at least a first optical fiber disposed within the fiber-reinforced composite section and along a length of the strength member,
wherein a first portion of the at least first optical fiber extends beyond at least one end of the fiber-reinforced composite strength member;
an optical time domain reflectometer operatively connected to the first portion of the first optical fiber.

21. The system recited in claim 20, wherein the distance that the first optical fiber portion extends beyond the one end of the strength member is at least about 5 cm.

22. The system recited in any one of claim 20 or 21, wherein the distance that the first optical fiber portion extends beyond the one end of the strength member is not greater than about 40 cm.

23. The system recited in any one of claims 20 to 22, wherein the first optical fiber is disposed near an outer circumferential surface of the strength member.

24. The system recited in any one of claims 20 to 23, wherein the strength member includes at least a second optical fiber element embedded in the binding matrix and extending along the length of the composite strength member, and wherein a first portion of the second optical fiber element extends a distance beyond the one end of the fiber-reinforced composite strength member, and wherein the optical time domain reflectometer is operatively connected to the first portion of the second optical fiber.

25. The system recited in any one of claims 20 to 24, wherein the strength member has a length of at least about 500 meters.

26. The system recited in any one of claims 20 to 25, further comprising a protective tube disposed around the first portion of the first optical fiber to protect the first portion from damage.

27. The system recited in claim 26, wherein the protective tube is fabricated from a metallic material or a hard plastic material.

28. The system recited in any one of claim 26 or 27, wherein the first optical fiber extends into a case and into a connector disposed at an opposite end of the case, wherein the connector operatively connects the optical time domain reflectometer to the first optical fiber.

29. The system recited in any one of claim 26 or 27, wherein the strength member includes a conductive layer wrapped around the strength member.

30. The system recited in any one of claim 29, wherein the overhead electrical conductor is strung upon a plurality of support towers.

31. A method for the connection of a strength member configured for use in an overhead electrical cable and having a first composite end and a second composite end, the strength member comprising a binding matrix, a plurality of reinforcing fibers operatively disposed within the binding matrix to form a fiber-reinforced composite section, and at least a first optical fiber disposed within the fiber-reinforced composite section and along a length of the strength member, the method comprising the steps of:
polishing an end of the strength member to form a smooth end surface, including an end of the first optical fiber;
aligning the end of the first optical fiber to a first end of a fiber probe using a 3-D stage to control the movement of the fiber probe.

32. The method recited in claim 31 wherein a second end of the fiber probe is operatively connected to a visual monitor to facilitate alignment of the end of the first optical fiber to the first end of the fiber probe.

33. The method recited in claim 32, comprising the step of, after the aligning step:
operatively disconnecting the visual monitor from the fiber probe; and
operatively connecting an optical time domain reflectometer to the second end of the fiber probe.

34. The method recited in claim 33, wherein the steps of operatively disconnecting and operatively connecting comprise using an optical switch or a fiber optic splitter to alter the optical path between the monitor and the optical time domain reflectometer.

35. A method for operatively connecting an optical fiber to a light analysis device, where the optical fiber is disposed in a fiber-reinforced composite comprising reinforcing fibers disposed in a binding matrix, comprising the step of selectively removing the binding matrix from the optical fiber at an end of the fiber-reinforced composite to expose a portion of the optical fiber.

36. The method recited in claim 35, wherein the step of selectively removing the binding matrix comprises heating the binding matrix.

37. The method recited in claim 36, wherein the heating step comprises contacting the binding matrix with a torch.

38. The method recited in claim 36, wherein the step of selectively removing the binding matrix comprises contacting the binding matrix with an acidic solution.

39. The method recited in any one of claims 35 to 38, further comprising the step of applying a coating to the portion of the optical fiber.

40. The method recited in claim 39, wherein the coating is a polymer coating.

41. The method recited in any one of claims 35 to 40, wherein the exposed portion of the optical fiber has a length of at least about 5 cm.
